(19) United States
(12) Patent Application Publication
(10) Pub. No.: US 2004/0006733 A1
(43) Pub. Date: Jan. 8, 2004

(54) Method for repairing received signal and equalizer

(76) Inventors: Ari Hamalainen, Vantaa (FI); Jukka Henriksson, Espoo (FI)

Correspondence Address: ANTONELLI, TERRY, STOUT & KRAUS, LLP, 1300 NORTH SEVENTEENTH STREET, SUITE 1800, ARLINGTON, VA, 22209-9889, US

(21) Appl. No.: 10/189,237

(22) Filed: Jul. 5, 2002

(51) Int. Cl. H03M 13/00; H03M 13/03

(52) U.S. Cl. 714/752

(57) ABSTRACT

A method for repairing a channel-encoded phase modulation signal deteriorated in radio path, and an equalizer and receiver operating according to said method. In the repairing of the received signal (r) is utilized data corrected with respect to bit errors, which data is achieved by channel coding and decoding and interleaving. For this purpose, a feedback signal is formed by re-encoding and reinterleaving the decoded signal. This way bits (\hat{b}), correspoding to symbol bits of the signal received from the channel but in addition estimating the original data, are provided. The equalizer (EQ) is an iteration-type. After each iteration cycle, to the result is added the corresponding bit estimate being included in the feedback signal for the next cycle. When the result has settled, it is taken forward on the signal path without said bit estimate. A wide iteration cycle, accompanied by parts belonging to channel coding and interleaving (DEIL, DEC, ENC, IL), can be repeated for a few times with the same data for further reducing errors. In the equalizer as well as in the decoder (DEC) analog technology, instead of digital iteration, can be used in searching for the equilibrium of bit values.

The invention relates to a method for repairing a channel encoded phase modulation signal deteriorated in a radio path. The invention also relates to an equalizer and a receiver functioning in accordance with said method.

The propagation of a radio signal in an environment with changing form is multipath type. That it is pronouncedly in cellular networks in residential areas, where there are plenty of surfaces reflecting radio waves. Digital information to be transferred is in so-called symbols, which are contained in a baseband signal that modulates a carrier. As a result of multipath propagation, a transmitting corresponding to a certain symbol arrives at a receiving antenna at different times, and there may be parts from different symbols in a whole signal arriving at a certain moment. Also limited bandwidth of the radio channel results in signal distortion. Then again, the quality of the signal is made worse by noise and interference accumulating on the signal in the transmission path. Furthermore, the properties of the transmission path can temporarily change in an unforeseen manner.

In order that information, or data, provided by a receiver, would be like the original data, plurality of functions aiming for reliability of transmission are made in a transmitter that operates e.g. according to some mobile communication networks' radio system. These include channel coding taking into account the nature of a channel, interleaving and modulation way. In this description and claims, channel means a transmission path having a certain bandwidth and aforementioned encumbrances caused by the environment. In channel coding, the redundancy of a digital signal to be transferred is increased such that bit errors caused by the channel do not nearly always lead to bit errors in the decoded signal. In mobile communication networks some convolutional codes are used for channel coding. In interleaving, digital signal bytes are spread by changing the order of bits so that a typical temporary interference is distributed into the range of several original bytes. This supports the reducing of bit errors realized by convolutional coding. The modulation method is selected so that the frequency range reserved for a channel is used efficiently, which for its part has an effect on the reduction of bit errors. In this respect, phase modulations (PSK, phase shift keying) are advantageous: The momentary phase of a carrier is set on grounds of bits to be transmitted. The bits that are taken in the modulator at the same time form an above-mentioned symbol. If only one bit at a time is taken in the modulator, the symbols then being one-bit type, there is at issue a binary PSK (BPSK). For example in the GSM900 system, an improved version of BPSK, i.e. Gaussian minimum shift keying (GMSK), is used. Among others, in systems applying EDGE technology (enhanced date rates for global evolution), the number of bits is three, in which case the carrier has eight optional phases. Thus there is at issue the 8-PSK.

Distortion in the signal caused by a channel is often so great that the signal necessarily must be repaired at the receiver before decoding. The repairing, of course, requires knowledge about the nature of the channel, for which reason the channel must be modeled in the equalizer. In conventional equalizers, an inverted model is formed such that the product of the channel's transfer function and the transfer function of the ideal model is one. Suitable for the purpose is a FIR type (finite impulse response) filter, where samples of the received signal are stored in consecutive memory elements. The temporary storage places for the samples are called channel taps. The repaired signal is provided as a weighted sum of the stored samples. The weighting coefficients are set with the help of a so-called training period. In that case a known pilot signal is sent, and the received and repaired signal is compared with a flawless pilot signal being in the equalizer's memory. Error is tried to eliminate by adjusting the weighing coefficients so that for example the square sum of the error signal is minimized.

The above-described principle does not bring about an optimal repairing of a received signal. In theory, if the noise caused by the channel is normally distributed and symbols appear statistically just as often, the optimal repairing is achieved when the cost function ƒ(B) according to equation (1) is minimized.

$$f ( B ) = {\sum }_{k = 0}^{K - 1} {‖ {r}_{k} - {\sum }_{i = 0}^{N - 1} {h}_{i} {S}_{k - i} ( B ) ‖}^{2} \qquad ( 1 )$$

where B means bits contained in symbols, or symbol bits,

S(B) is an individual symbol,

N is the number of the channel taps in the channel model,

hᵢ is a coefficient in the channel model,

r is a sample of an input signal and

K is the number of transferred symbols.

The bits corresponding to the minimum of function ƒ(B) are more likely the same as the sent bits. The minimum definitely would be found by calculating square sum according to equation (1) for each possible symbol sequence and choosing the sequence corresponding to the smallest sum. This kind of calculation is in practice unrealistic because of the enormous number of calculations; the number depends exponentially on the number of received symbols. Pretty much the same result can be achieved by using the Viterbi algorithm, where variables used in decision-making are calculated recursively from step to step and unlikely symbol sequences are discarded after each step, or symbol time. The number of calculations depends in this case only linearly on the number of received symbols, however exponentially on the length of the memory chain storing samples, or on the number of channel taps. This leads to the fact that due to the number of necessary channel taps in practice, the Viterbi algorithm does not come into question for example in mobile communications networks.

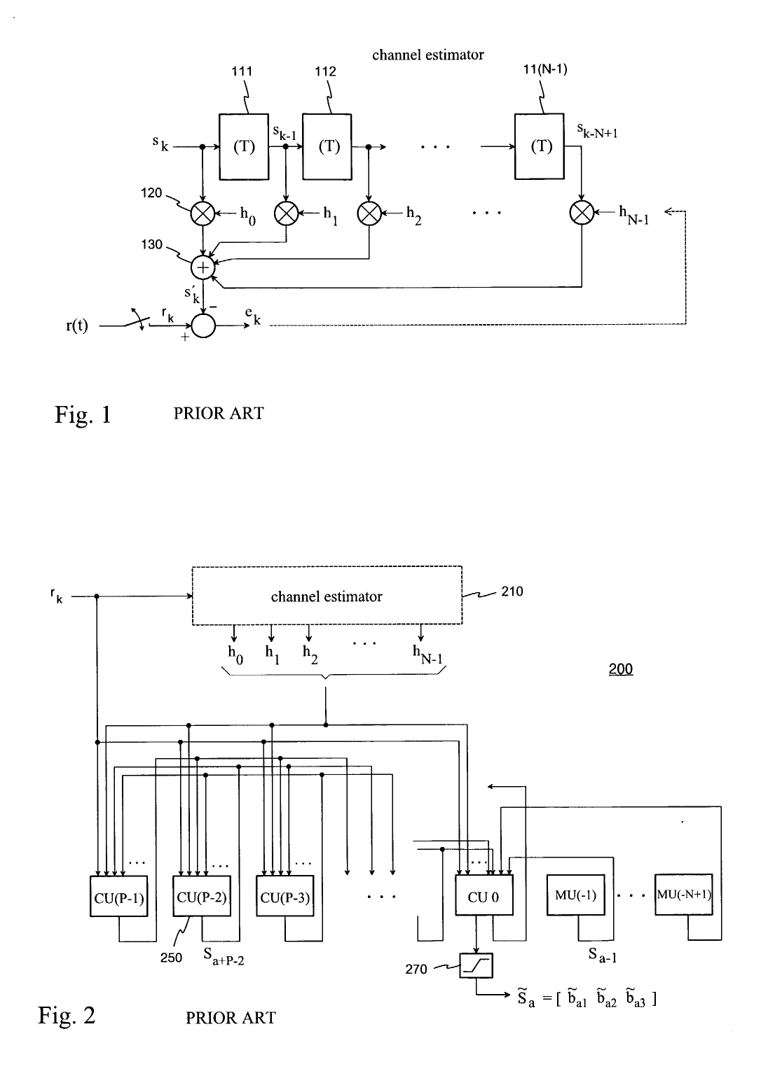

In methods based on equation 1, coefficients h modeling the real channel are needed. In FIG. 1 there is an example of a modeling structure, or channel estimator. Also in this case a FIR filter and a training period are used for modeling. The input signal of the filter is r(t), which corresponds to the sent pilot signal. The spectrum of signal r(t) already is transferred to the baseband area after the accomplished receiving from the transmission path. It includes noise caused by transmission path, and associated with each symbol there may be energy originating in other symbols. From signal r(t), samples are taken in intervals, the length of which is symbol time T. The symbol time means the duration of an individual symbol in signal r(t). Samples are converted into digital form, which results in a digital sample queue signal rₖ. The structure comprises N−1 memory elements 111, 112, . . . , 11(N−1) connected in series, so the number of channel taps is N. A sample signal sₖ, corresponding to the symbols of flawless pilot signal being in the estimator's memory, is fed into these memory elements. In FIG. 1, the notation sₖ indicates also the newest sample coming into the memory chain. Then the previous sample sₖ₋₁ is the first memory element 111, the one previous to that is in the second memory element 112 etc. The newest sample is multiplied with a certain number ho in the first multiplier 120. Correspondingly the previous samples are multiplied in order with certain numbers h₁, h₂ . . . , h_{N-1}. The resulting numbers are added in the adder 130, whose output signal s′ₖ equals the signal sₖ “deteriorated” by the model channel. Signal s′ₖ is sample by sample subtracted from the signal rₖ, deteriorated by the real channel. The square sum of the error signal eₖ is calculated, and such values that result in minimum of mean square error are sought for h numbers, or coefficients. The calculation is done with complex numbers.

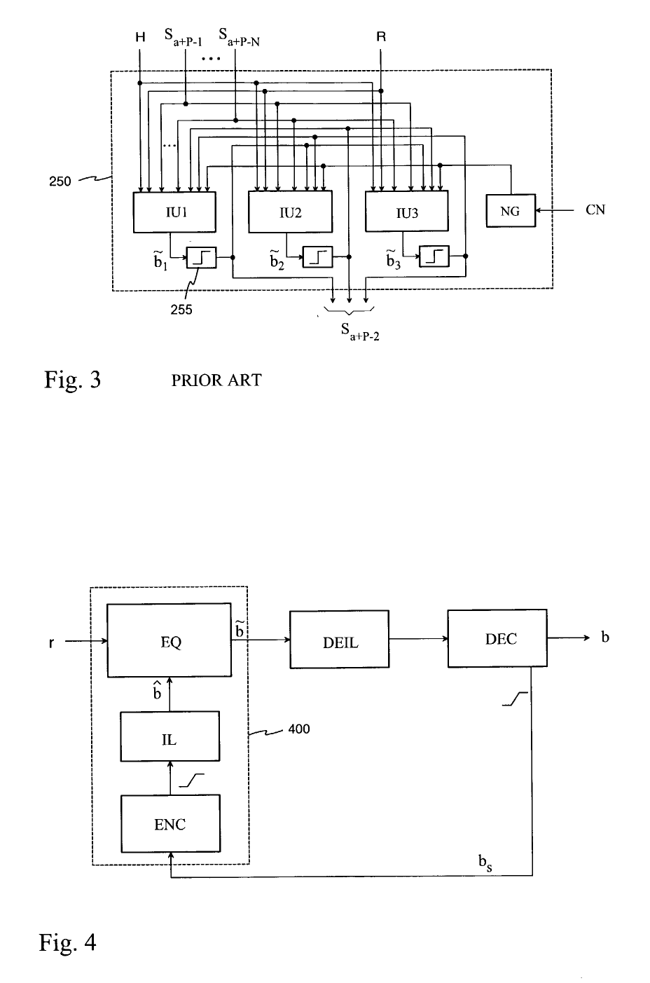

From application publication FI 20002819 is known an equalizer according to FIGS. 2 and 3. The principle is that an expression according to equation (1) is differenced in respect to symbol bits what operate as variables, and a zero point is sought iteratively for the difference. In accordance with the principle, the following expression can be led to realize an equalizer.

$${\tilde{b}}_{l m} = {\sum }_{k = l}^{l + N - 1} re [ {r}_{k}^{*} {h}_{k - l} \frac{Δ {S}_{l} ( B )}{Δ {b}_{l m}} ] - re [ {h}_{k - l}^{*} \frac{Δ {S}_{l}^{*} ( B )}{Δ {b}_{l m}} {\sum }_{q = 0 , k - q \neq l}^{N - 1} {h}_{q} {S}_{k - q} ( B ) ] + AWGN \qquad ( 2 )$$

where r, h ja N are the same as in equation (1),

bₗₘ is the value of bit m of symbol Sₗ(B) at the start of an iteration cycle,

l is the index of the symbols,

m is the index of the bits of individual symbol,

re[z] is the real part of complex number z,

z* is the complex conjugate of number z,

AWGN is noise (Additive White Gaussian Noise) and

\tilde{b}ₗₘ is the value of bit m of symbol Sₗ(B), given by an individual iteration cycle.

In case of 8-PSK, symbol Sₗ(B) can mathematically be expressed as follows. The expression shows how the phase of carrier depends on symbol bits.

Sₗ(B)=a\overline{b}ₗ₁bₗ₂bₗ₃+a²\overline{b}ₗ₁bₗ₂\overline{b}ₗ₃+a³\overline{b}ₗ₁\overline{b}ₗ₂\overline{b}ₗ₃+a⁴\overline{b}ₗ₁\overline{b}ₗ₂bₗ₃+a⁵bₗ₁\overline{b}ₗ₂bₗ₃+a⁶bₗ₁\overline{b}ₗ₂\overline{b}ₗ₃+a⁷bₗ₁b₁₂\overline{b}ₗ₃+a⁸bₗ₁bₗ₂bₗ₃

where bₗ₁, bₗ₂ and bₗ₃ are bits B of symbol Sₗ(B),

\overline{b}ₗₓ=1−bₗₓ and

a=e^{iπ/4}, i is the imaginary unit here.

FIG. 2 shows roughly the functional structure of an equalizer. The equalizer 200 comprises a channel estimator 210, which is e.g. according to FIG. 1. The channel estimator gives the coefficients h₀, h₁, . . . , h_{N-1}, the number of channel taps then being N. The actual equalizer is formed of P calculation units CU(P−1), CU(P−2), . . . , CU0, similar among themselves, and (N−1) memory units MU(−1), MU(−2), . . . , MU(−N+1), similar among themselves. Coefficients h are taken in each calculation unit. A certain part of the whole incoming sample queue rₖ is taken in each individual calculation unit. The output signal of each calculation unit is taken in a certain number of adjacent units. This number can be N−1, for instance. The total number P of calculation units corresponds to the number of consecutive symbols simultaneously involved in the calculation. In principle, the more calculation units there are, the better the signal can be repaired. In practice, the number P can be for example 5N; a larger number hardly improves the result. In memory units are stored N−1 symbols, of which there have already been decisions made. These symbols are used in calculation unit CU0, in addition to newer, still undecided symbols. In repairing a certain symbol, the effects of both previous symbols and following symbols are taken into account. The final calculation result is taken out from the calculation unit CU0. In FIG. 2 this is carried out by a soft decision through a soft limiter 270. The result is a symbol \tilde{S}ₐ, which in the figure's example has three bits. Soft decision means that each of three bits bₐ₁, bₐ₂, bₐ₃ is presented as a multi-bit number at this point. After a symbol is taken out from the equalizer, a new sample is taken in, and the whole sample queue is shifted by a step in both calculation units CU and in memory units MU. The calculation can also be arranged to be parallel so that several symbols can be taken out at the same time. They can be taken out from successive units CU0, CU1, . . . , CU(Q−1), where Q is number of shifting steps before a new calculation.

FIG. 3 shows roughly the functional structure of calculation units. Calculation unit CU(P−2) marked with reference number 250 was chosen for the figure. Calculation unit comprises iteration units IU1, IU2, IU3, similar to each other and whose number is the same as the number of symbol bits. A part of the incoming sample queue, corresponding to the calculation unit under consideration, along with the coefficients h provided by the channel model, are taken in the iteration units. In addition, output signals of adjacent calculation units are used as input signals, as was mentioned above. In FIG. 3 these output signals are symbols S_{a+P-1}−S_{a+P-N}, except for symbol S_{a+P-2}, which are in formation phase. Inside the calculation unit, the output signal, or bit information, of each iteration unit is, after hard decision, taken in the input of other iteration units. One of three hard limiters is marked in FIG. 3 with reference number 255. The calculation unit further comprises a noise generator NG, noise samples generated by which are taken in each iteration unit. By such a structure, each iteration unit of the calculation unit calculates, according to equation (2), a value \tilde{b}ₘ, m=1, 2 or 3, for one symbol bit. A similar calculation is repeated and the result is compared to the previous result. This is continued until there is no longer a significant difference between consecutive results. Alternatively, a pre-selected number of iteration cycles is performed. In the first iteration cycle, when there is not yet a previous result, the bits are given random initial values. The bit values may as a result of iteration cycles settle at levels that correspond to such a minimum of equation's (1) expression that is not the “deepest” minimum. This type of minimum is called a local minimum. Adding noise samples to bit signals reduces possibility of ending up at a local minimum. The noise level is reduced from cycle to cycle with control signal CN. An additional way is to do the same calculation several times with different initial values, and the one corresponding to the deepest minimum is chosen from the results.

In FIGS. 2 and 3 as well as 5 the calculation and iteration units are functional units. Their practical implementation is mostly programmatic in a same processor unit

In the above-depicted solution, the amount of calculation naturally depends on the number of iteration cycles and on the selected number of assuring calculations. However, the dependency on the number of channel taps is in principle polynomial and not exponential as in the Viterbi algorithm. For this reason, the amount of calculation is in practice significantly smaller than with Viterbi. The performance of the method is lower than with a pure Viterbi, but for example in the same class as with DDFSE (delayed decision-feedback sequence estimation), applied Viterbi. The DDFSE is an equalizer improved over a usual equalizer. It has an internal feedback from the chain containing already selected symbols. The Viterbi algorithm is used in this feedback chain. The number of elements in the feedback chain is smaller than the number of equalizer channel taps.

The purpose of the invention is to implement a repairing of signal received from a radio path in a manner that is more efficient than known manners. The method according to the invention is characterized by what is presented in independent claim 1. An equalizer according to the invention is characterized by what is presented in independent claim 14. A receiver according to the invention is characterized by what is presented in independent claim 21. Advantageous embodiments of the invention are presented in the other claims.

The basic idea of the invention is as follows: In the repairing of the received signal is utilized data corrected with respect to bit errors, which data is achieved by channel coding and decoding and interleaving. For this purpose, a feedback signal is formed by re-encoding and reinterleaving the decoded signal. This way bits, corresponding to symbol bits of the signal received from the channel but in addition estimating the original data, are provided. The equalizer is an iteration-type. After each iteration cycle, to the result is added the corresponding bit estimate being included in the feedback signal, for the next cycle. When the result has settled, it is taken forward on the signal path without said bit estimate. A wide iteration cycle, accompanied by parts belonging to channel coding and interleaving, can be repeated for a few times with the same data for further reducing errors. In the equalizer as well as in the decoder analog technology, instead of digital iteration, can be used in searching for the equilibrium of bit values.

An advantage of the invention is that the bit error ratio becomes lower compared to known techniques. This is because the bit information (bit estimates) based on data subsequent to channel decoding and taken in the equalizer forces the symbol bit values toward levels being probably more correct than levels where they would settle without the bit information in question. Decision-making subsequent to equalizing produces fewer faulty 0/1-decisions, which furthermore results in that the decoder has qualifications to more accurately correct the bit errors that remain. Another advantage of the invention is that it retains a relatively small amount of calculation, characteristic of iterative equalizing. This is emphasized when using analog circuits.

The invention is described in detail below. In the description is referred to the enclosed drawings, where

FIG. 1 presents an example of an equalizer according to the prior art,

FIG. 2 presents another example of an equalizer according to the prior art,

FIG. 3 presents more precisely the core part of the structure of FIG. 2,

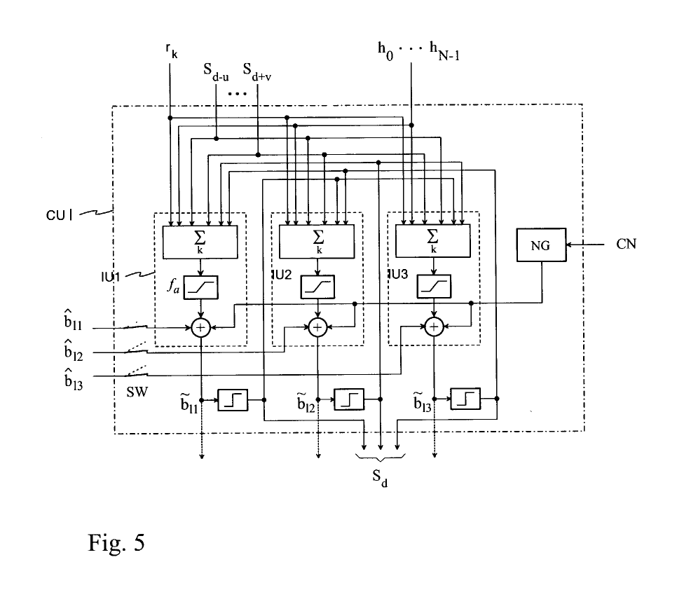

FIG. 4 presents the principle of the invention as a block diagram,

FIG. 5 presents an example of the core part of an equalizer according to the invention,

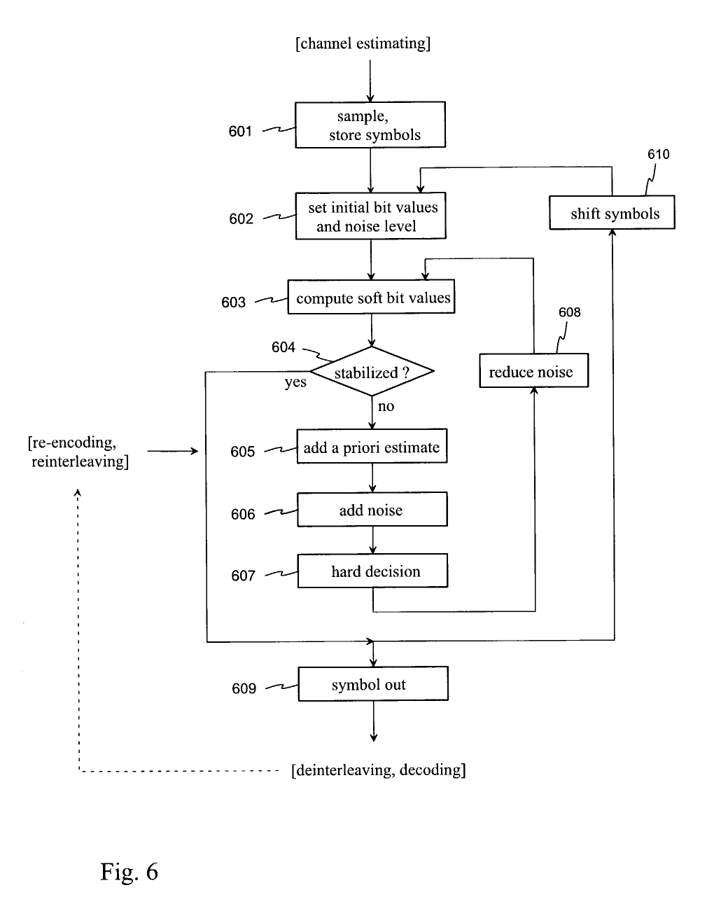

FIG. 6 presents the method according to the invention as a flow diagram and

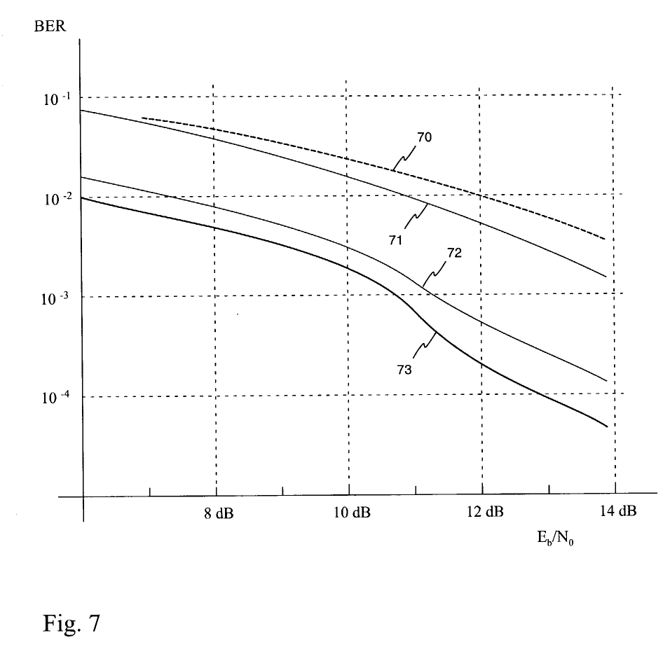

FIG. 7 presents a simulation result of the performance of equalizer according to the invention.

FIGS. 1, 2 and 3 were explained in conjunction with the description of the prior art.

In FIG. 4 there is, as a block diagram, a part of a receiver according to the invention. The input signal is r, which is assumed to be channel-coded and interleaved at the sending end. The channel code is typically some convolution code. The input signal is taken in the equalizer EQ, which is an iterative equalizer like in FIG. 2. From the equalizer the signal path continues, as usual, to a deinterleaver DEIL and from here to a unit decoding the channel code, or decoder DEC. The decoder can be one basing on the Viterbi-algorithm or for example a neural-type. In all cases it advantageously uses soft decision. The decoder produces data bits b, aimed to be the same as the original data bits at the sending end. The structure further comprises a channel encoder ENC and subsequent to that an interleaver IL, which units function according to the same rules as the corresponding units in the transmitter. The encoder's input signal bₛ is taken from the decoder DEC after a soft decision, whereupon in signal bₛ, e.g. a four-bit number, corresponds to each final data bit. Channel encoder ENC is a “soft encoder”, therefore also its output bits are multi bit numbers. The interleaver gives signal \hat{b}, where bits are arranged in the same way as in the symbols generated from the signal coming from the radio path to the equalizer. A substantial difference is that in signal \hat{b} there is information about bit error corrections, performed by the channel decoding, and thus so-called a priori information about the original data. The bits of signal \hat{b} are taken in equalizer EQ, where they, according to the invention, are used as certain kinds of guides in directing the iteration processes in the direction considered correct. Equalizer EQ, encoder ENC and interleaver IL form an expanded equalizer 400 according to the invention.

In FIG. 5 there is an example of an individual calculation unit CU1 of an equalizer according to the invention. This is similar to the calculation unit presented in FIG. 3 with the difference that said signal \hat{b} is now taken in the calculation unit. In the example the symbols have three bits, therefore also in the signal \hat{b}a symbol corresponding to the calculation unit in question includes three bits \hat{b}₁₁, \hat{b}₁₂, \hat{b}₁₃. These are taken in different iteration units. The information provided by signal bis taken into account in iterative unit m according to the following equation:

$${\tilde{b}}_{l m} = {f}_{a} \{ {\sum }_{k = l}^{l + N - 1} re [ {r}_{k}^{*} {h}_{k - l} \frac{Δ {S}_{l} ( B )}{Δ {b}_{l m}} ] - re [ {h}_{k - l}^{*} \frac{Δ {S}_{l}^{*} ( B )}{Δ {b}_{l m}} {\sum }_{q = 0 , k - q \neq l}^{N - 1} {h}_{q} {S}_{k - q} ( B ) ] \} + {\hat{b}}_{l m} + AWGN \qquad ( 3 )$$

The notations used in equation (3) are the same as in equation (2). Notation ƒₐ means a function used in the soft decision. That function has values in the range of −1 . . . +1. A course of the function in that range is linear or non-linear. After a soft decision, bit \hat{b}ₗₘ and noise are added. The sum bit \tilde{b}ₗₘ is used after a hard decision in following iteration cycle. So in FIG. 5 a particular symbol S_{d} has been gotten out to be taken in adjacent calculation units. Bits \hat{b} are used only during the iteration for guiding it. If at issue is such a calculation unit whose bits are taken out from the equalizer, the output bits are bits \tilde{b} provided by soft decision, without bits \hat{b}. Accordingly, these are not added into the iteration results at that phase.

In FIG. 6 there is an example of the method according to the invention. A channel estimating has been done as a preceding operation, and as result a set of coefficients corresponding to the number of taps in the channel model are available. In method step 601 the sampling of the incoming signal is continued, which signal now contains information to be transferred, and samples corresponding to individual symbols are stored. In step 602, in the equalizer's calculation units e.g. random initial values are set for the bits of each symbol, and the starting level of noise is set. In step 603, new values for symbol bits are calculated with algorithm minimizing the cost function of equation (1) and a soft decision is made for the results. Next, in step 604, is checked whether the bit values already are settled. If not, an a priori estimate bit provided by recoding and reinterleaving, and a noise sample are summed according to steps 605 and 606 into each bit value. In step 607, a hard decision is made for results provided this way. In step 608 the noise level produced by the noise generator is lowered. After this it is returned to step 603, or to the calculation of new bit values. In the calculation, for each bit, coefficients of the channel model and information about states of other bits of the symbol and states of bits of adjacent symbols, provided by said hard decision, are used. If in step 604 it is found that the bit values have been settled sufficiently accurate, the bit values of one symbol provided by the soft decision are taken out of the equalizer (step 609) for deinterleaving and decoding. The a priori estimate bits and noise are not summed into the bits to be taken out of the equalizer. The level of noise, on the other hand, already is very low in this operation phase. At the same time, the shifting of symbols, required to continue the operation, occurs in the calculation units, step 610. After this it is returned to step 602.

The operation corresponding to steps 603-608 of FIG. 6 can also be arranged using analog technology. In analogue circuit operation there are no separate phases or separate iteration cycles. The output voltages of the circuit settle to certain levels as a result of continuous transition phase, forced by the feedback. In patent claims, even this operation is called “iterative” in order to emphasize the similarity with the digital calculation.

In FIG. 7 there is an example of a simulation result showing the performance of an equalizer according to the invention. In the simulation model a fading four-path channel is used as transmission path. The channel has been estimated using a 26-symbol long training period. The number of iteration cycles is 200.

Graph 71 shows the result when the calculation is once done in such a manner that the parts belonging to channel coding and interleaving are involved. Let's call that calculation “wide calculation”. Graph 72 shoes the result when the calculation is repeated using as a starting basis the symbol bit values and decoded bit values given by the previous calculation. Graph 73 shows the result when the calculation is repeated using as the starting basis the symbol bit values and decoded bit values given by the second calculation. According to the results, when the average bit energy with respect to the noise spectral power density is for example 8 dB, the bit error ratio improves from a value of 0.04 to a value of 0.008 and furthermore to 0.005 when repeating wide calculation. There is thus clearly a benefit from repeating. In decibels the advantage is more than 4 when comparing graphs 71 and 73. Graph 70 shows corresponding result when using an iterative equalizer without the feedback according to the invention. In comparing the graphs 70 and 71, it is seen that the method according to the invention produces a better result even without repeating the wide calculation.

Above a method according to the invention and its applicable receiver for the part of repairing received signal are described. Not all of the optional method and arrangement points are of course presented. The present inventive idea can be applied in a number of ways in the scope of the independent claims.

1. A method for repairing in a receiver symbols of a channel-encoded signal, deteriorated in radio path of a transmission system, in which receiver bits of repaired symbols are channel-decoded, the method comprising the following steps;
the channel used for transmission is modeled by seeking coefficients to be applied to consecutive samples,
a certain number of samples of received signal are stored,
initial values for bits of symbols corresponding to said samples are set in a memory,
an iterative settling of values of symbol bits to states, where a cost function describing a degree of intersymbol interference achieves a minimum, is arranged, using for each bit said coefficients of the channel model and information about states of other bits of the symbol in question and states of bits of adjacent symbols,
a decision is made about bits of at least one symbol and
for a new calculation, symbol queue in the memory is shifted by the number of steps being the same as a number of decided symbols,
wherein
the decoded bits are re-encoded and
during said iterative settling the bits provided by re-encoding are further used in repairing of symbols to utilize bits corrected by means of decoding.

2. A method according to claim 1, wherein during said iterative settling
new values for symbol bits are calculated with algorithm minimizing the cost function, based on previous bit values,
it is examined whether the new bit values differ significantly from the previous bit values,
calculation is repeated for each bit until the new bit values no longer significantly differ from the previous bit values.

3. A method according to claim 1, wherein during said iterative settling
new values for symbol bits are calculated with algorithm minimizing the cost function, based on previous bit values,
the calculation is repeated a specified number of times.

4. A method according to claims 2 and 3, said algorithm being
$${\tilde{b}}_{l m} = {f}_{a} \{ {\sum }_{k = l}^{l + N - 1} re [ {r}_{k}^{*} {h}_{k - l} \frac{Δ {S}_{l} ( B )}{Δ {b}_{l m}} ] - re [ {h}_{k - l}^{*} \frac{Δ {S}_{l}^{*} ( B )}{Δ {b}_{l m}} {\sum }_{q = 0 , k - q \neq l}^{N - 1} {h}_{q} {S}_{k - q} ( B ) ] \} + {\hat{b}}_{l m} + AWGN$$
where S(B) is an individual symbol,
bₗₘ is the value of bit m of symbol Sₗ(B) at the start of an iteration cycle after hard decision,
N is the number of the channel taps in the channel model,
hⱼ is a coefficient in the channel model,
rₖ is a sample of the input signal to be repaired,
K is the number of transferred symbols,
l is the index of the symbols,
m is the index of the bits of individual symbol,
re[z] is the real part of complex number z,
z* is the complex conjugate of number z,
\hat{b}ₗₘ is a value of symbol's Sₗ(B) bit m given by re-encoding,
ƒₐ is a function used in soft decision,
\tilde{b}ₗₘ is a value of symbol's Sₗ(B) bit m given by an iteration cycle and AWGN is noise.

5. A method according to claim 1, whereupon interleaving is used in the transmission system in addition to the channel coding, the signal being reinterleaved after re-encoding to utilize bits corrected by means of decoding in repairing of symbols.

6. A method according to claim 1, said re-encoding being soft.

7. A method according to claim 1, a channel code used in the transmission system being a convolution code.

8. A method according to claim 1, a modulation used in the transmission system being a digital phase modulation.

9. A method according to claim 1, said initial values for bits of symbols being random.

10. A method according to claim 1, wherein during said iterative settling noise is added to each bit value to reduce probability of bit values ending up in a local minimum, and a level of the noise is lowered with proceeding of the iteration.

11. A method according to claim 1, wherein the step when said iterative settling is arranged, is repeated with the different initial values for bits, and bit value set corresponding to deepest local minimum is selected.

12. A method according to claim 1, wherein the steps when said iterative settling is arranged and a decision is made about bits of at least one symbol, are repeated with the same symbols using in the re-encoding new decoded bits based on previous calculation.

13. A method according to claim 1, wherein the step when said iterative settling is arranged, is realized by an analog circuit corresponding an algorithm minimizing said cost function, in which analog circuit the iterative settling is arranged by continuous feedback.

14. An equalizer for repairing symbols of a channel-encoded signal, deteriorated in radio path of a transmission system, the equalizer comprising
means to sample signal received from the radio path,
means to store certain number of samples,
means to seek coefficients modeling the channel,
means to iteratively calculate values of symbol bits in a way that reduces a cost function describing a degree of intersymbol interference, which means are arranged to use for each bit said coefficients and information about states of other bits of the symbol in question and states of bits of adjacent symbols,
means to make a decision about bits of at least one symbol at a time,
wherein the equalizer further comprises a channel encoder to re-encode decoded signal and an interleaver to reinterleave an output signal of said encoder, and said means to iteratively calculate values of symbol bits are arranged to further utilize bits provided by said encoder and interleaver.

15. An equalizer according to claim 14, said means to iteratively calculate values of symbol bits comprising
a program, using an algorithm that minimizes said cost function, to calculate new values for symbol bits based on previous bit values,
an arrangement to repeat for each symbol bit a calculation according to said algorithm, if new bit values differ significantly from previous bit values.

16. An equalizer according to claim 14, said means to iteratively calculate values of symbol bits comprising
a program, using an algorithm that minimizes said cost function, to calculate new values for symbol bits based on previous bit values,
an arrangement to repeat a specified number of times a calculation according to said algorithm.

17. An equalizer according to claim 14, said encoder being an encoder of soft encoding.

18. An equalizer according to claim 14, said means to iteratively calculate values of symbol bits comprising random number generators to give initial values for symbol bits.

19. An equalizer according to claim 14, said means to iteratively calculate values of symbol bits comprising adjustable noise generators to add noise to bit values in order to reduce probability of bit values ending up in a local minimum.

20. An equalizer according to claim 14, said means to iteratively calculate values of symbol bits comprising an analog circuit corresponding an algorithm minimizing said cost function, in which analog circuit the iterative settling is arranged by continuous feedback.

21. A receiver comprising an equalizer for repairing symbols of a channel-encoded signal, deteriorated in radio path of a transmission system, a deinterleaver and a channel decoder, which equalizer has
means to sample signal received from the radio path,
means to store certain number of samples,
means to seek coefficients modeling the channel,
means to iteratively calculate values of symbol bits in a way that reduces a cost function describing a degree of intersymbol interference, which means are arranged to use for each bit said coefficients and information about states of other bits of the symbol in question and states of bits of adjacent symbols,
means to make a decision about bits of at least one symbol at a time,
wherein the receiver further comprises a channel encoder to re-encode a decoder output signal and an interleaver to reinterleave an output signal of said encoder, and said means to iteratively calculate values of symbol bits are arranged to further utilize bits provided by said encoder and interleaver.

22. A receiver according to claim 21, said decoder being a decoder of soft decoding.

23. A receiver according to claim 21, said decoder being a neural decoder.
